(19) United States
(12) Patent Application Publication
(10) Pub. No.: US 2026/0136892 A1
(43) Pub. Date: May 14, 2026

(54) SEMICONDUCTOR STRUCTURE WITH DAISY CHAIN AND INSPECTION METHOD USING THE DAISY CHAIN

(71) Applicant: TAIWAN SEMICONDUCTOR MANUFACTURING COMPANY LTD., HSINCHU (TW)

(72) Inventors: CHENG-YU HSIEH, KAOHSIUNG CITY (TW); YANG-CHE CHEN, HSIN-CHU CITY (TW); WEI-YU CHOU, HSINCHU (TW); HSIANG-TAI LU, HSINCHU COUNTY (TW); WEI-RAY LIN, HSINCHU CITY (TW)

(21) Appl. No.: 18/945,592

(22) Filed: Nov. 13, 2024

(51) Int. Cl. H01L 21/66; H01L 23/00; H01L 23/498; H01L 25/00; H01L 25/03; H01L 25/10

(52) U.S. Cl. CPC H10P 74/207; H10W 70/65; H10W 90/00; H10W 90/701; H10W 70/60; H10W 90/722; H10W 90/724

(57) ABSTRACT

A method for inspecting a bonded structure includes: bonding a first semiconductor structure to a second semiconductor structure through a plurality of first conductive connectors between a first surface of the first semiconductor structure and the second semiconductor structure, wherein the first conductive connectors are electrically connected to each other by a plurality of first conductive lines within the second semiconductor structure; applying a voltage to the first conductive connectors through at least one of a plurality of second conductive connectors to obtain an electrical parameter, wherein the second conductive connectors are disposed at a second surface of the first semiconductor structure and electrically connected to the first conductive connectors; and evaluating a bonding status associated with the first conductive connectors according to the electrical parameter. The first conductive connectors are arranged adjacent to a corner or a periphery of the first semiconductor structure.

### BACKGROUND

As semiconductor technologies evolve, three-dimensional (3D) integrated circuits (ICs) emerge as an effective alternative to further reduce the physical size of a semiconductor chip. Typically, bonded structures allow for higher yield, greater connection densities, smaller form factors, and improved cost-effectiveness.

However, the manufacture of the bonded structures involves many steps and operations to form such small and thin semiconductor structures. An increase in complexity of the manufacture of the bonded structures may cause deficiencies such as poor bonding, delamination of components, or other issues, resulting in a high yield loss of the semiconductor device. As such, there is a need to efficiently examine the bonded structures during the manufacturing process.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a cross-sectional view of a bonded structure, in accordance with some embodiments of the present disclosure.

FIG. 2 is a cross-sectional view of the bonded structure in FIG. 1 disposed on a circuit board, in accordance with some embodiments of the present disclosure.

FIG. 3 is a schematic plan view of a portion of the bonded structure in FIG. 2, in accordance with some embodiments of the present disclosure.

FIG. 4 is a cross-sectional view of another bonded structure, in accordance with some embodiments of the present disclosure.

FIG. 5 is a schematic plan view of a portion of the bonded structure in FIG. 4, in accordance with some embodiments of the present disclosure.

FIG. 6 is a flowchart showing a method for inspecting a bonding status or a connection status between a first semiconductor structure and a second semiconductor structure to form the bonded structure in FIG. 2, in accordance with some embodiments of the present disclosure.

FIGS. 7 to 13 are schematic cross-sectional views illustrating sequential operations of the method in FIG. 6, in accordance with some embodiments of the present disclosure.

FIGS. 14 to 16 are cross-sectional views showing some operations of the method in FIG. 6 used for the bonded structure in FIG. 4.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies.

Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In some cases, poor bonding or joint failure may occur when bonding two semiconductor structures. Such problem may arise due to various causes, such as cold solder joints, misalignment, or the like. Poor bonding or joint failure is determined manually, such as examination performed by taking X-rays or cutting cross-sections. Such methods are inefficient and time-consuming. The present disclosure provides a bonded structure including one or more daisy chains for inspecting a bonding status. The present disclosure also provides an inspection method.

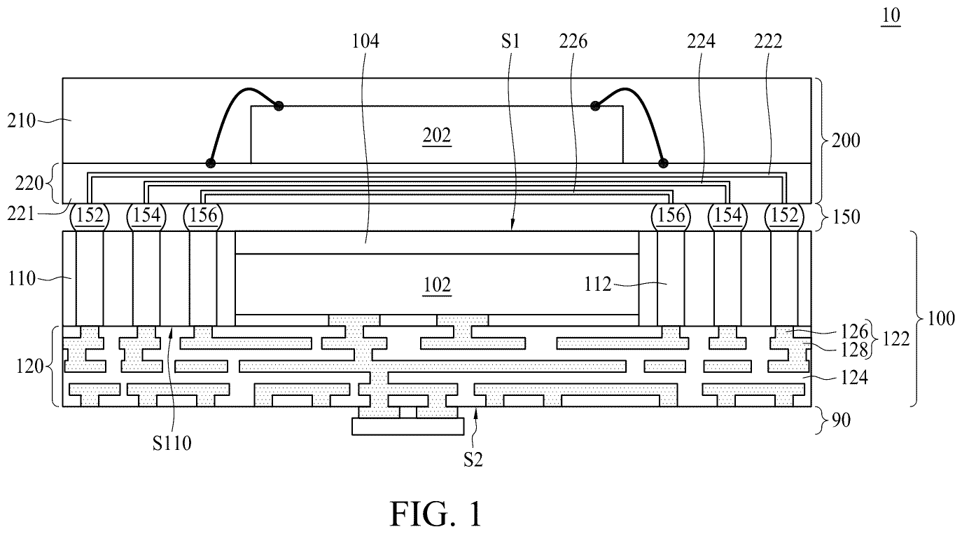

FIG. 1 is a cross-sectional view of a bonded structure 10, according to some embodiments of the present disclosure. In some embodiments, the bonded structure 10 is a stacked structure having several chips or dies stacked over each other. In some embodiments, the bonded structure 10 is a package-on-package (PoP) structure, in which packages are stacked over each other. In some embodiments, the bonded structure 10 includes a system on integrated circuit (SoIC) structure, an integrated fan out (InFO) structure, or the like.

In some embodiments, the bonded structure 10 includes a first semiconductor structure 100 bonded to a second semiconductor structure 200. The first semiconductor structure 100 has a first surface S1 and a second surface S2 opposite to the first surface S1. The second semiconductor structure 200 is disposed over the first surface S1 of the first semiconductor structure 100.

In some embodiments, multiple conductive connectors 150 are disposed between the first semiconductor structure 100 and the second semiconductor structure 200. FIG. 1 shows only some of the connectors 150. The conductive connectors 150 are disposed on the first surface S1 of the first semiconductor structure 100. The conductive connectors 150 are made of a conductive material such as solder, copper, nickel, gold, or the like. In some embodiments, the conductive connectors 150 are solder balls, microbumps (μbumps), controlled collapse chip connection (C4) bumps, pads, pillars, or the like. The conductive connectors 150 are used for connecting the second semiconductor structure 200 to the first semiconductor structure 100.

The first semiconductor structure 100 includes a first chip 102 surrounded by a molding member 110. In some embodiments, the first chip 102 includes active devices such as transistors and/or passive devices such as resistors, capacitors and inductors. In some embodiments, the first chip 102 is a system on a chip (SoC), a central processing unit (CPU) die, a graphic processing unit (GPU) die, a micro control unit (MCU) die, an input-output (IO) die, a baseband (BB) die, an application processor (AP) die, an application specific integrated circuit (ASIC) die, or the like. The molding member 110 may be formed by epoxy, resin, and/or other materials. Multiple through vias 112 are disposed in the molding member 110. The through vias 112 extend vertically through the molding member 110 for connecting conductive members over and under the through vias 112.

In some embodiments, the first semiconductor structure 100 is a fan-out structure, which includes input/output (I/O) terminals fanning out from the first chip 102 and extending beyond a periphery of the first chip 102. In some embodiments, the first semiconductor structure 100 includes a redistribution layer (RDL) 120. In some embodiments, the RDL 120 is a circuit board. In some embodiments, the RDL 120 is free of active devices. In some other embodiments, active devices such as transistors are formed in the RDL 120.

The RDL 120 includes redistribution wirings 122 surrounded by a dielectric layer 124. In some embodiments, the redistribution wirings 122 are electrically connected to the first chip 102. The redistribution wirings 122 include multiple conductive vias 126 and multiple conductive lines 128 connected to each other. The conductive lines 128 extend laterally at different levels in the dielectric layer 124. A number of the levels of the conductive lines 128 is not limited. The conductive vias 126 extend vertically for connecting the conductive lines 128 at different levels. The dielectric layer 124 may include a dielectric material such as silicon oxide, silicon nitride, silicon carbide, silicon oxynitride, polymer, polybenzoxazole (PBO), polyimide, benzocyclobutene (BCB), or the like.

In some embodiments, I/O terminals of the first chip 102 are fanned out and redistributed over the first chip 102 across a greater area. In some embodiments, the RDL 120 re-routes a path from the first chip 102 to redistribute I/O terminals of the first chip 102 at a bottom surface S110 of the molding member 110. In some embodiments, the first chip 102 is disposed in a face-down manner, that is, an active surface of the first chip 102 faces the RDL 120, and a rear surface of the first chip 102 faces the second semiconductor structure 200. In some embodiments, a die attach film (DAF) 104 is formed on the rear surface of the first chip 102. In such embodiments, a surface of the DAF 104 is substantially level with a surface of the molding member 110. The surface of the DAF 104 and the surface of the molding member 110 are portions of the first surface S1.

The second semiconductor structure 200 includes a second chip 202 surrounded by an encapsulating member 210. In some embodiments, the second chip 202 includes active devices such as transistors and/or passive devices such as resistors, capacitors and inductors. In some embodiments, the second chip 202 is a volatile memory such as a dynamic random-access memory (DRAM), a static random-access memory (SRAM), or the like. In some embodiments, the second chip 202 is a non-volatile memory such as a NOR flash, a NAND flash, or the like. The encapsulating member 210 may be formed by epoxy, resin, and/or other materials.

In some embodiments, the second semiconductor structure 200 includes a circuit board 220. In some embodiments, the circuit board 220 is free of active devices such as transistors and diodes. In some other embodiments, the circuit board 220 also includes active devices such as transistors and/or passive devices such as resistors, capacitors and inductors. The second chip 202 is bonded to the circuit board 220 and the encapsulating member 210 is disposed on the circuit board 220.

In some embodiments, the circuit board 220 includes first, second and third circuits 222, 224 and 226 surrounded by a dielectric layer 221. The dielectric layer 221 may include a dielectric material such as silicon oxide, silicon nitride, silicon carbide, silicon oxynitride, polymer, polybenzoxazole, polyimide, benzocyclobutene, or the like.

In some embodiments, the first, second and third circuits 222, 224 and 226 are used for testing or inspecting a bonding status between the first semiconductor structure 100 and the second semiconductor structure 200. The first, second and third circuits 222, 224 and 226 may be referred to as test circuits. In some embodiments, the first circuit 222, the second circuit 224 and the third circuit 226 are separated from each other and electrically independent. In some embodiments, none of the first, second and third circuits 222, 224 and 226 is electrically connected to the second chip 202. In some embodiments, the first, second and third circuits 222, 224 and 226 extend laterally in the dielectric layer 221. In some embodiments, a length of the first circuit 222 is greater than a length of the second circuit 224, and the length of the second circuit 224 is greater than a length of the third circuit 226.

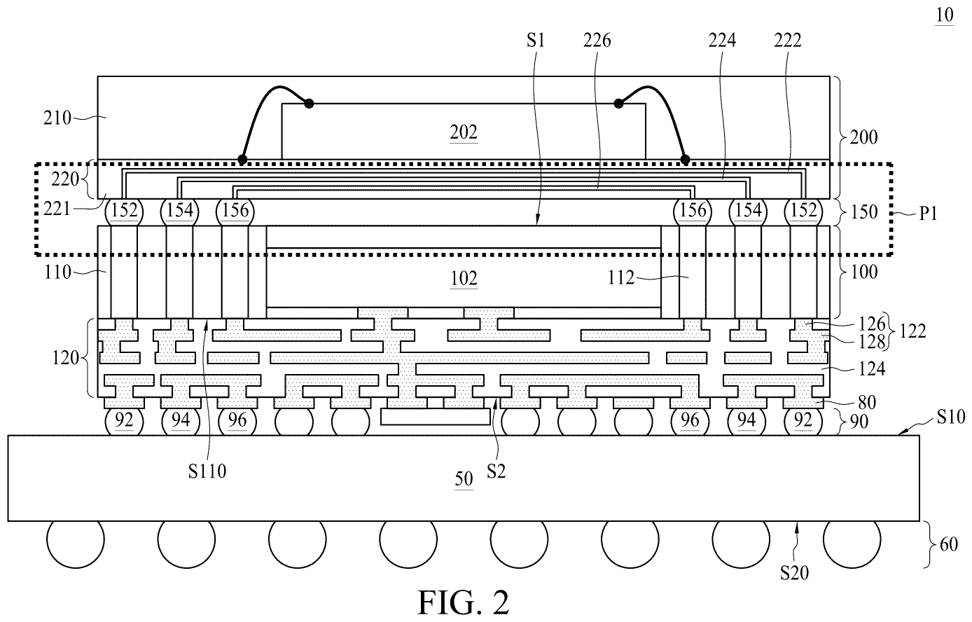

FIG. 2 is a cross-sectional view of the bonded structure 10 disposed on a circuit board, according to some embodiments of the present disclosure. In some embodiments, the bonded structure 10 is mounted on a circuit board 50 such as a printed circuit board (PCB) via multiple conductive pads 80 and multiple conductive connectors 90. The conductive pads 80 are disposed on the second surface S2 of the first semiconductor structure 100 and electrically connected to the RDL 120. Each conductive connector 90 is disposed on a conductive pad 80. The conductive pads 80 and the conductive connectors 90 are made of a conductive material such as solder, copper, nickel, gold, or the like. In some embodiments, the conductive connectors 90 are solder balls, microbumps, C4 bumps, pillars, or the like. The conductive connectors 90 are configured to connect the first semiconductor structure 100 to an external circuitry or a ground. The conductive connectors 90 are electrically connected to the conductive connectors 150 via the RDL 120 and the through vias 112. In some embodiments, the conductive connector 90 and the conductive connector 150 have different sizes or configurations. For example, the conductive connector 90 may be substantially larger than the conductive connector 150. In other embodiments, the conductive connector 90 and the conductive connector 150 have substantially same size and configuration.

Multiple conductive connectors 60 may be disposed on a second surface S20 opposite to the first surface S10 of the circuit board 50. The conductive connectors 60 are made of a conductive material such as solder, copper, nickel, gold, or the like. In some embodiments, the conductive connectors 60 are solder balls, ball grid array (BGA) bumps, or the like. In some embodiments, the circuit board 50 includes a grounding trace (not shown).

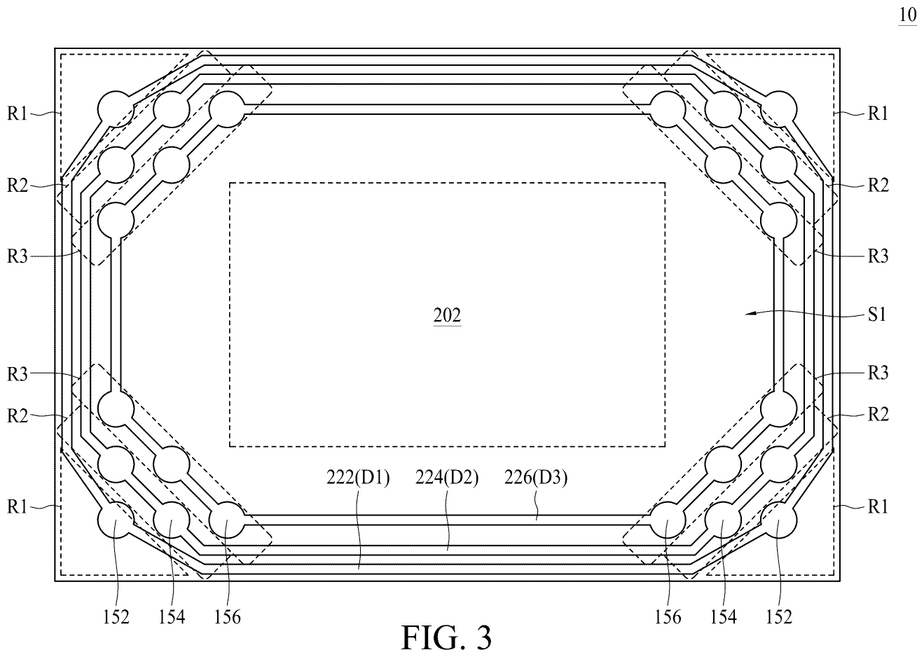

FIG. 3 is a schematic plan view of a portion P1 of the bonded structure 10 in FIG. 2. In some embodiments, the conductive connectors 150 are arranged adjacent to a corner or a periphery of the first surface S1 of the first semiconductor structure 100. The corner or the periphery of the first surface S1 may have a first region R1, a second region R2 and a third region R3 from an outside to an inside of the first surface S1. For ease of discussion, the conductive connectors 150 disposed in the first region R1 are labelled as conductive connectors 152, the conductive connectors 150 disposed in the second region R2 are labelled as conductive connectors 154, and the conductive connectors 150 disposed in the third region R3 are labelled as conductive connectors 156. A number of the conductive connectors 150 in each of the regions R1, R2 and R3 is not limited.

In some embodiments, the conductive connectors 152 are electrically connected to each other in series, the conductive connectors 154 are electrically connected to each other in series, and the conductive connectors 156 are electrically connected to each other in series. In some embodiments, the conductive connectors 152 are electrically connected to each other by the first circuit 222 to form a first daisy chain D1, the conductive connectors 154 are electrically connected to each other by the second circuit 224 to form a second daisy chain D2, and the conductive connectors 156 are electrically connected to each other by the third circuit 226 to form a third daisy chain D3. The first, second and third daisy chains D1, D2 and D3 may be referred to as test structures or monitor structures.

In some embodiments, each of the first, second and third daisy chains D1, D2 and D3 has a ring shape in a top view, as shown in FIG. 3. The first, second and third daisy chains D1, D2 and D3 are separated from each other. In some embodiments, the third daisy chain D3 is surrounded by the second daisy chain D2, and the second and third daisy chains D2 and D3 are surrounded by the first daisy chain D1. The first daisy chain D1 is closer to the periphery of the first surface S1 of the first semiconductor structure 100 than the second and third daisy chains D2 and D3.

In some embodiments, in addition to the test circuits, the circuit board 220 includes multiple functional circuits (not shown) surrounded by the dielectric layer 221. In some embodiments, such functional circuits are electrically connected to the second chip 202, and are electrically isolated from the first, second and third daisy chains D1, D2 and D3.

In some embodiments, the RDL 120 also includes multiple functional circuits formed by portions of the conductive vias 126 and portions of the conductive lines 128. In some embodiments, such functional circuits are electrically connected to the first chip 102, and are electrically isolated from the first, second and third daisy chains D1, D2 and D3.

Referring to FIGS. 2 and 3, for ease of discussion, portions of the conductive connectors 90 from an outside to an inside of the second surface S2 are labelled as conductive connectors 92, 94 and 96, respectively. In some embodiments, the conductive connectors 92, 94 and 96 are electrically connected to the first, second and third daisy chains D1, D2 and D3, respectively.

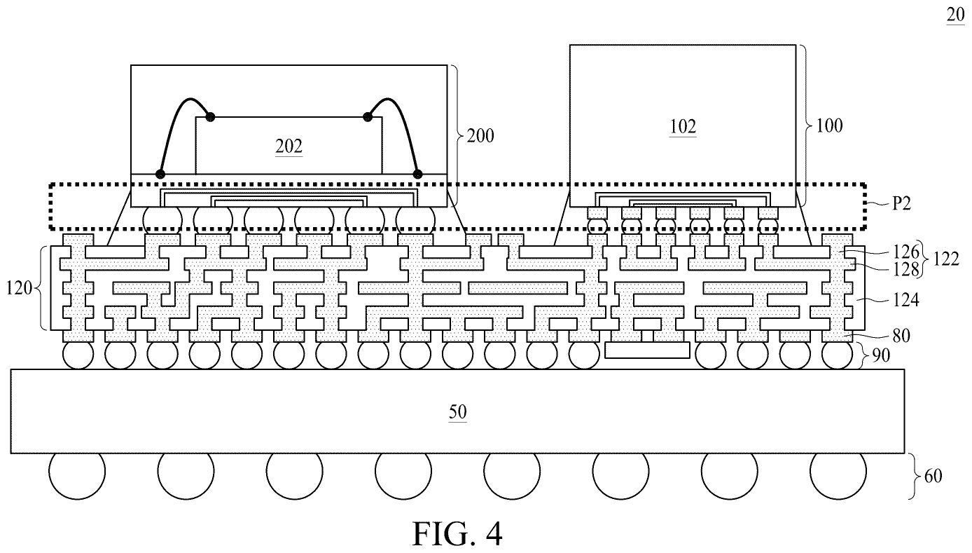

FIG. 4 is a cross-sectional view of a bonded structure 20, according to some embodiments of the present disclosure. The bonded structure 20 is similar to the bonded structure 10 in FIG. 2, except that in the bonded structure 20, the first semiconductor structure 100 and the second semiconductor structure 200 are disposed adjacent to each other and are both bonded to the RDL 120. The first chip 102 is electrically connected to the RDL 120 via a first set of conductive connectors, and the second chip 202 is electrically connected to the RDL 120 via a second set of conductive connectors. The first and second sets of conductive connectors may be separately surrounded by an underfill. In some embodiments, the first semiconductor structure 100 and the second semiconductor structure 200 separately include multiple test circuits embedded therein. The test circuits are similar to the first, second and third circuits 222, 224 and 226 in FIG. 2.

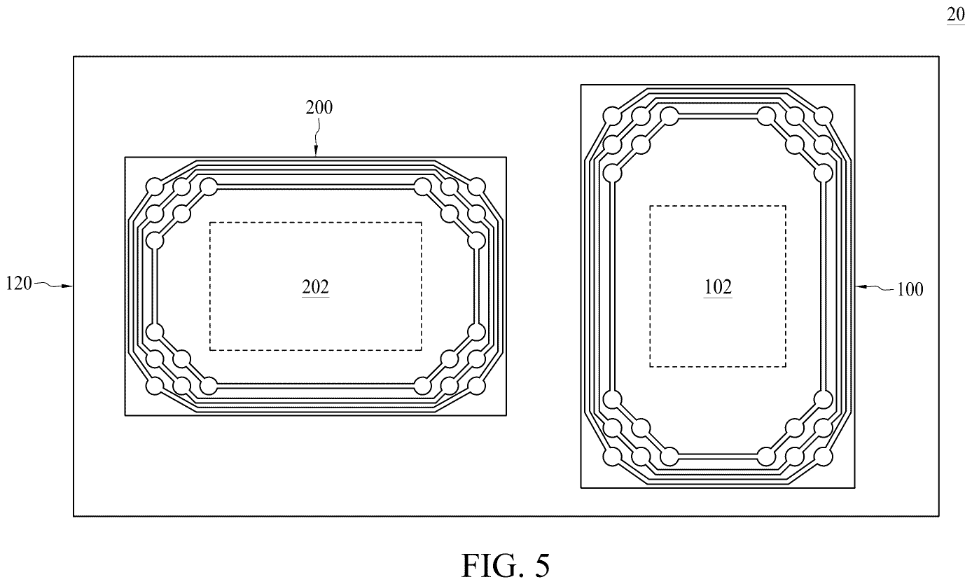

FIG. 5 is a schematic plan view of a portion P2 of the bonded structure 20 in FIG. 4. In some embodiments, the first set of conductive connectors under the first chip 102 are electrically connected to each other by the test circuits within the first semiconductor structure 100 to form multiple daisy chains. In some embodiments, the second set of conductive connectors under the second chip 202 are electrically connected to each other by the test circuits within the second semiconductor structure 200 to form multiple daisy chains. In some embodiments, the daisy chains formed by the first semiconductor structure 100 are electrically isolated from the daisy chains formed by the second semiconductor structure 200. In some embodiments, each of the daisy chains has a ring shape in a top view, as shown in FIG. 5.

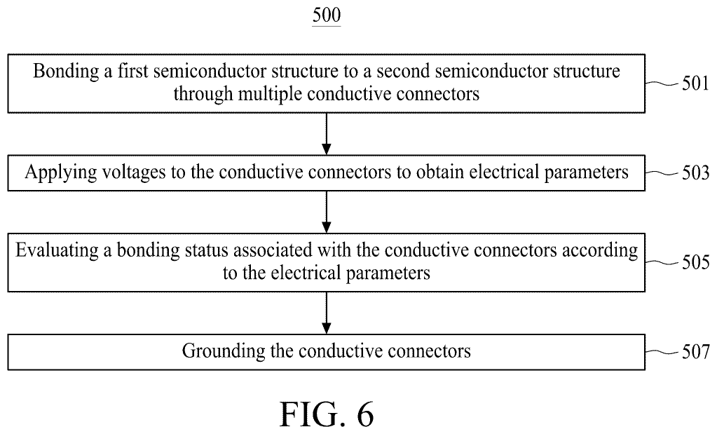

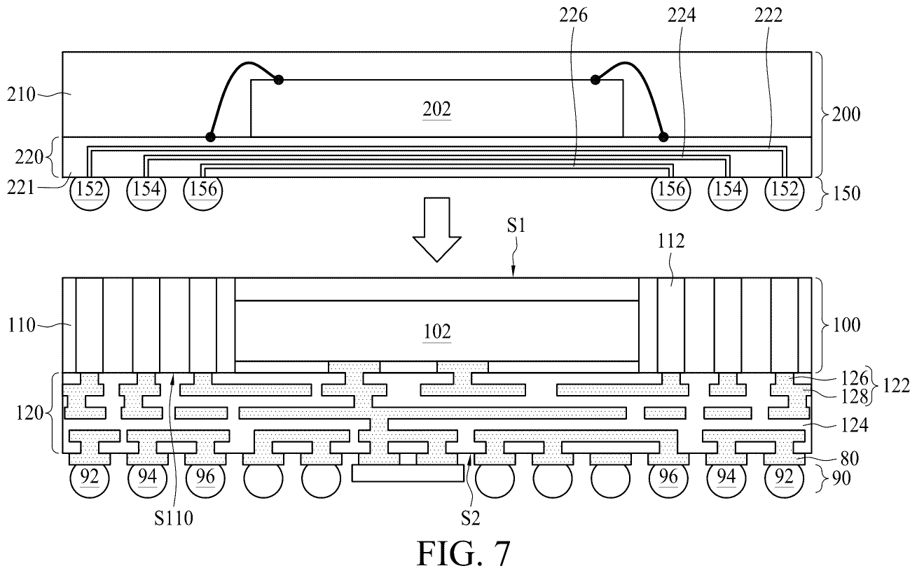

FIG. 6 is a flowchart showing a method 500 for inspecting a bonding status or a connection status between the first semiconductor structure 100 and the second semiconductor structure 200 after formation of the bonded structure 10 in FIG. 2, according to some embodiments of the present disclosure. The method 500 includes a number of operations and the description and illustrations are not deemed as a limitation to the sequence of the operations. FIGS. 7 to 13 are schematic cross-sectional views illustrating sequential operations of the method 500 in FIG. 6.

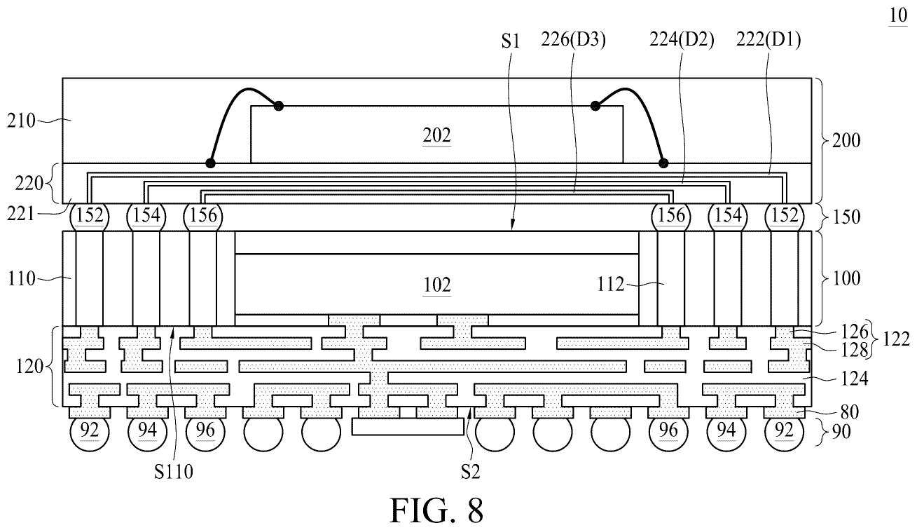

In operation 501 of FIG. 6, the first semiconductor structure 100 is bonded to the second semiconductor structure 200 through the conductive connectors 150, as shown in FIGS. 7 and 8. Referring to FIG. 7, only some of the conductive connectors 150 are shown. Other conductive connectors 150 may be disposed directly below the second chip 202. In some embodiments, the conductive connectors 150 are disposed on a lower surface of the second semiconductor structure 200 before the bonding. In some embodiments, the conductive connectors 150 are disposed on an upper surface (i.e., the first surface S1) of the first semiconductor structure 100 before the bonding. In other embodiments, first conductive members are disposed on an upper surface of the first semiconductor structure 100, and second conductive members are disposed on a lower surface of the second semiconductor structure 200 and respectively aligned with the first conductive members. In such embodiments, the conductive connectors 150 are formed by joining the first and second conductive members. In accordance with some embodiments, a practical arrangement of the conductive connectors 150 between the first semiconductor structure 100 and the second semiconductor structure 200 is shown in FIG. 3.

Referring to FIG. 8, after the bonded structure 10 is formed, the conductive connectors 150 are electrically connected to each other by the circuit board 220 within the second semiconductor structure 200. In some embodiments, one conductive connector 152 adjacent to an edge of the first semiconductor structure 100 is electrically connected to another conductive connector 152 adjacent to another edge of the first semiconductor structure 100 by the first circuit 222 to form the first daisy chain D1. In some embodiments, one conductive connector 154 adjacent to an edge of the first semiconductor structure 100 is electrically connected to another conductive connector 154 adjacent to another edge of the first semiconductor structure 100 by the second circuit 224 to form the second daisy chain D2. In some embodiments, one conductive connector 156 adjacent to an edge of the first semiconductor structure 100 is electrically connected to another conductive connector 156 adjacent to another edge of the first semiconductor structure 100 by the third circuit 226 to form the third daisy chain D3.

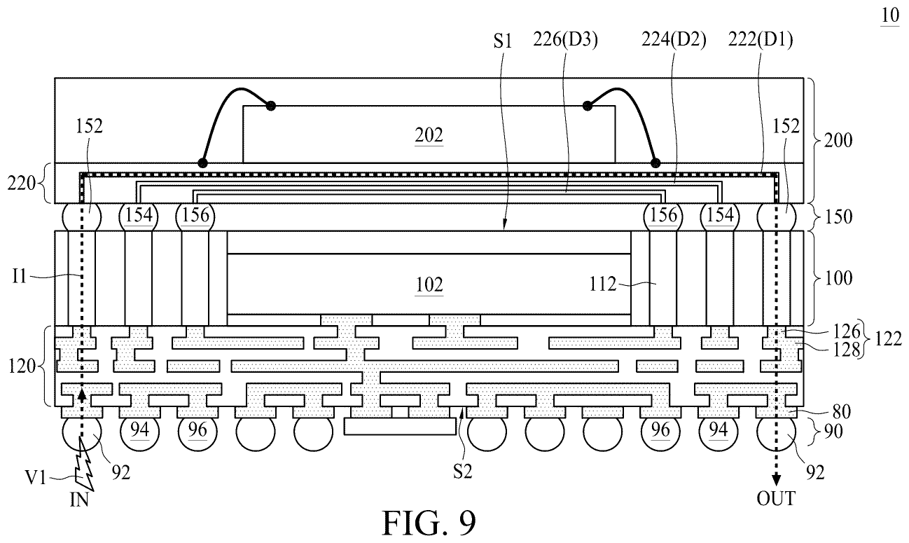

In operation 503 of FIG. 6, voltages are applied to the conductive connectors 150 to obtain electrical parameters, as shown in FIGS. 9 to 11. Since the conductive connectors 150 are electrically connected to the conductive connectors 90, in some embodiments, the voltages are applied by probing two terminals of the conductive connectors 90. For example, one the conductive connectors 92 is selected as a first terminal, and the other of the conductive connectors 92 is selected as a second terminal. An electrical test is executed by forming a temporary connection between the two terminals.

Referring to FIG. 9, a first voltage V1 is applied to one of the conductive connectors 92. In some embodiments, the first voltage V1 drives a first electrical current I1 to flow from the conductive connector 92 to another one of the conductive connectors 92. The first electrical current I1 flows through the RDL 120, the through vias 112, the conductive connectors 152 and the first circuit 222. In such embodiments, the first electrical current I1 flows through the first daisy chain D1. In some embodiments, the first voltage V1 is used to measure an electrical parameter or signal such as an electrical resistance of the first daisy chain D1. A first electrical resistance can be obtained by dividing the first voltage V1 by the first electrical current I1. Since the conductive connectors 152 bond the second semiconductor structure 200 to the first semiconductor structure 100, the first electrical resistance is associated with a degree of electrical conduction of the conductive connectors 152.

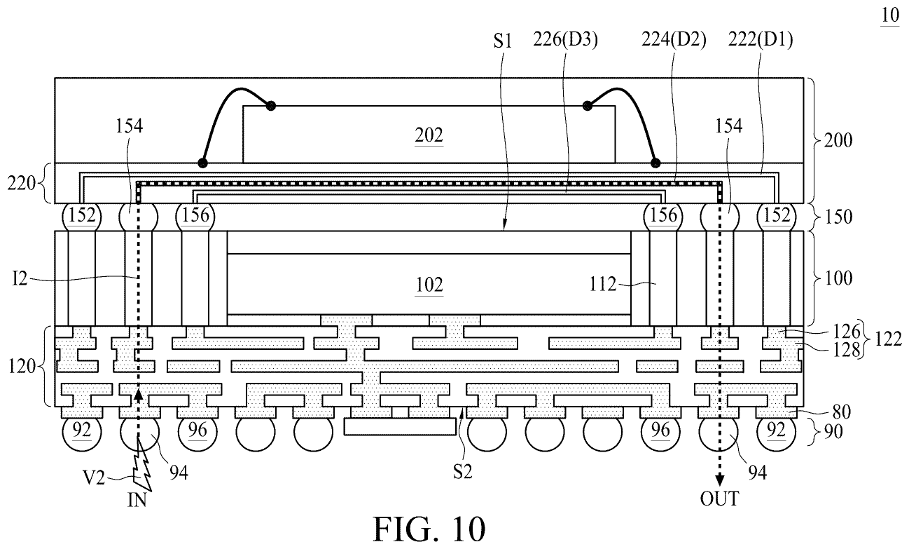

Referring to FIG. 10, a second voltage V2 is applied to one of the conductive connectors 94. The second voltage V2 may be identical to or different from the first voltage V1. In some embodiments, the second voltage V2 drives a second electrical current I2 to flow from the conductive connector 94 to another one of the conductive connectors 94. The second electrical current I2 flows through the RDL 120, the through vias 112, the conductive connectors 154 and the second circuit 224. In such embodiments, the second electrical current I2 flows through the second daisy chain D2. In some embodiments, the second voltage V2 is used to measure an electrical parameter or signal such as an electrical resistance of the second daisy chain D2. A second electrical resistance can be obtained by dividing the second voltage V2 by the second electrical current I2. Since the conductive connectors 154 bond the second semiconductor structure 200 to the first semiconductor structure 100, the second electrical resistance is associated with a degree of electrical conduction of the conductive connectors 154.

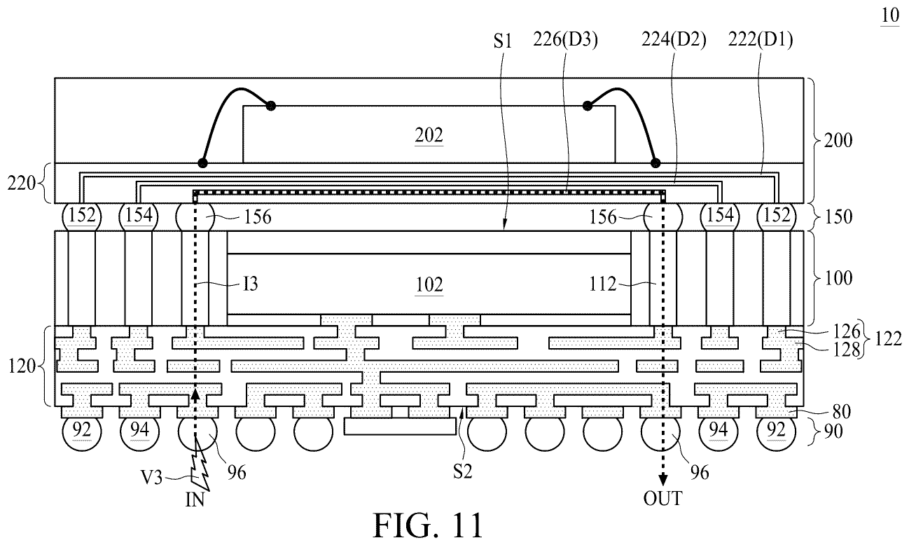

Referring to FIG. 11, a third voltage V3 is applied to one of the conductive connectors 96. The third voltage V3 may be identical to or different from the first voltage V1 or the second voltage V2. That is, the first, second and third voltages V1, V2 and V3 may have the same or different values. In some embodiments, the third voltage V3 drives a third electrical current I3 to flow from the conductive connector 96 to another one of the conductive connectors 96. The third electrical current I3 flows through the RDL 120, the through vias 112, the conductive connectors 156 and the third circuit 226. In such embodiments, the third electrical current I3 flows through the third daisy chain D3. In some embodiments, the third voltage V3 is used to measure an electrical parameter or signal such as an electrical resistance of the third daisy chain D3. A third electrical resistance can be obtained by dividing the third voltage V3 by the third electrical current I3. Since the conductive connectors 156 bond the second semiconductor structure 200 to the first semiconductor structure 100, the third electrical resistance is associated with a degree of electrical conduction of the conductive connectors 156. In other embodiments, the first, second and third voltages V1, V2 and V3 are applied separately and sequentially. In other embodiments, the first, second and third voltages V1, V2 and V3 are applied simultaneously. In such embodiments, the first, second and third electrical currents I1, I2 and I3 are electrically isolated from each other.

In operation 505 of FIG. 6, a bonding status associated with the conductive connectors 150 is evaluated according to the electrical parameters, as shown in FIGS. 9 to 11. Referring to FIG. 9, in some embodiments, the measured first electrical resistance is used for evaluating a joining status of the conductive connectors 152 or inspecting a bonding defect of the conductive connectors 152. If the measured first electrical resistance equals a predetermined value, the bonding of the conductive connectors 152 is determined to be acceptable. For example, when the first daisy chain D1 is in a closed circuit, the bonding of the conductive connectors 152 is determined to be successful. Otherwise, if the measured first electrical resistance is not equal to the predetermined value, the bonding of the conductive connectors 152 is determined to have failed. For example, when the measured first electrical resistance is significantly greater than the predetermined value, the first daisy chain D1 is determined to be in an open circuit. For example, when the measured first electrical resistance is significantly less than the predetermined value, the first daisy chain D1 is suspected to be in a short circuit. Such situations indicate that the bonding of the conductive connectors 152 is problematic.

Referring to FIG. 10, in some embodiments, the measured second electrical resistance is used for evaluating a joining status of the conductive connectors 154 or inspecting a bonding defect of the conductive connectors 154. If the measured second electrical resistance equals a predetermined value, the bonding of the conductive connectors 154 is determined to be acceptable. For example, when the second daisy chain D2 is in a closed circuit, the bonding of the conductive connectors 154 is determined to be successful. Otherwise, if the measured second electrical resistance is not equal to the predetermined value, the bonding of the conductive connectors 154 is determined to have failed. For example, when the measured second electrical resistance is significantly greater than the predetermined value, the second daisy chain D2 is determined to be in an open circuit. For example, when the measured second electrical resistance is significantly less than the predetermined value, the second daisy chain D2 is suspected to be in a short circuit. Such situations indicate that the bonding of the conductive connectors 154 is problematic.

Referring to FIG. 11, in some embodiments, the measured third electrical resistance is used for evaluating a joining status of the conductive connectors 156 or inspecting a bonding defect of the conductive connectors 156. If the measured third electrical resistance equals a predetermined value, the bonding of the conductive connectors 156 is determined to be acceptable. For example, when the third daisy chain D3 is in a closed circuit, the bonding of the conductive connectors 156 is determined to be successful. Otherwise, if the measured third electrical resistance is not equal to the predetermined value, the bonding of the conductive connectors 156 is determined to have failed. For example, when the measured third electrical resistance is significantly greater than the predetermined value, the third daisy chain D3 is determined to be in an open circuit. For example, when the measured third electrical resistance is significantly less than the predetermined value, the third daisy chain D3 is suspected to be in a short circuit. Such situations indicate that the bonding of the conductive connectors 156 is problematic.

Still referring to FIG. 11, compared to the conductive connectors 152, the conductive connectors 154 and 156 are disposed closer to the inside of the first surface S1. When the second electrical resistance is not equal to the predetermined value and/or the third electrical resistance is not equal to the predetermined value, the bonding between the first semiconductor structure 100 and the second semiconductor structure 100 is determined to be problematic. The problematic bonding may arise from a warpage of the first semiconductor structure 100 and/or a warpage of the second semiconductor structure 100.

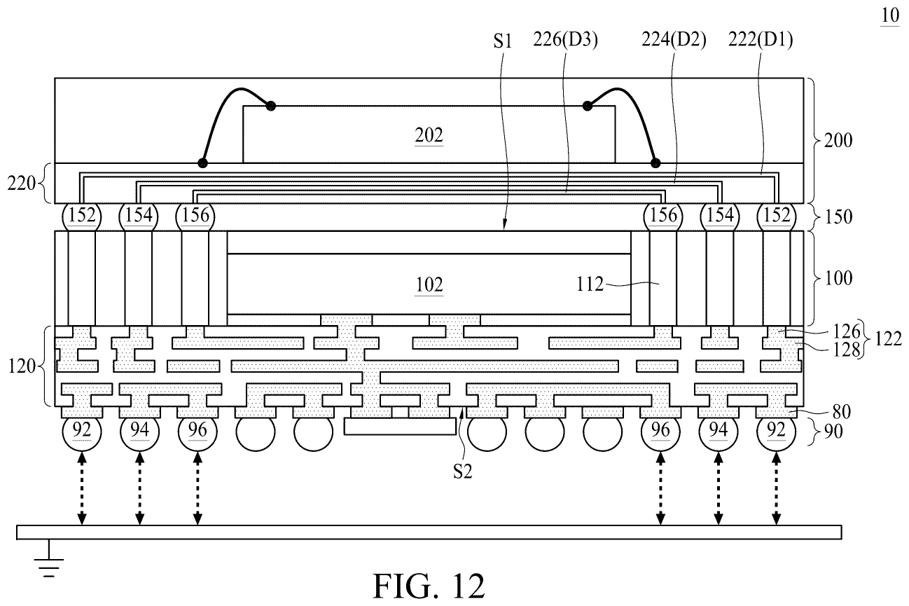

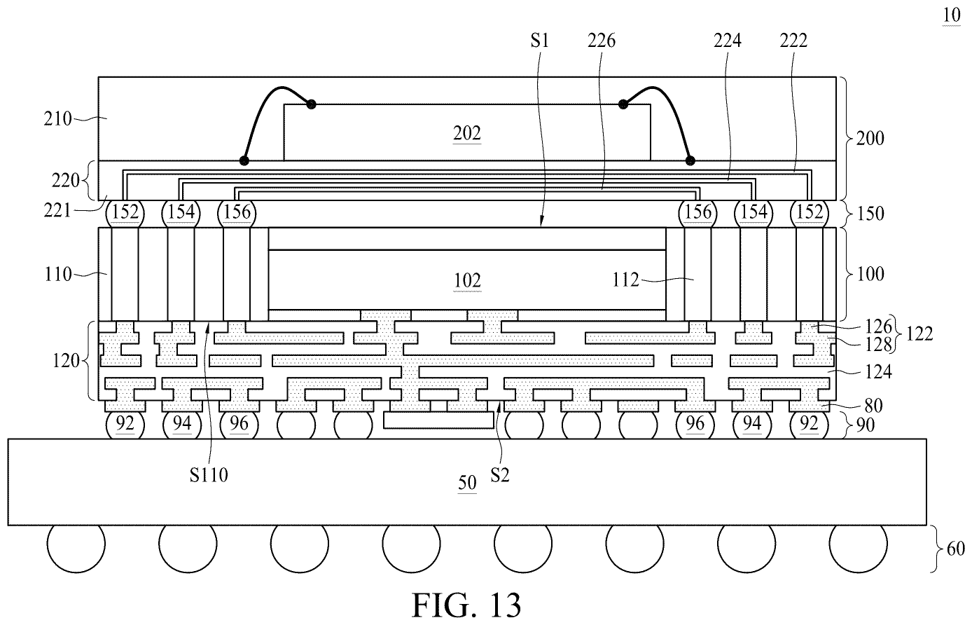

In operation 507 of FIG. 6, the conductive connectors 150 are grounded, as shown in FIGS. 12 and 13. Referring to FIG. 12, FIG. 12 is a schematic cross-sectional view showing a grounding operation. In some embodiments, the grounding of the conductive connectors 150 is achieved by grounding the conductive connectors 90. In some embodiments, some of the conductive connectors 90 such as the conductive connectors 92, 94 and 96 are grounded, and others of the conductive connectors 90 connected to the functional circuits in the RDL 120 are not grounded.

Referring to FIG. 13, FIG. 13 is an example showing the grounding of the conductive connectors 90. In some embodiments, the conductive connectors 90 are bonded to the circuit board 50 after the application of voltages. In some embodiments, the conductive connectors 90 are bonded to the circuit board 50 after the bonding status associated with the conductive connectors 150 is evaluated. The circuit board 50 having grounding traces is provided. In some embodiments, the bonded structure 10 is mounted on the circuit board 50 with the conductive connectors 92, 94 and 96 electrically connected to the grounding traces in the circuit board 50. As a result, the first, second and third daisy chains D1, D2 and D3 are electrically grounded after the bonding status associated with the conductive connectors 150 is monitored. That is, the first, second and third daisy chains D1, D2 and D3 are not “floating,” which can prevent electrical interference from the test structures.

In other embodiments, the circuit board 50 does not include a grounding trace. The first, second and third daisy chains D1, D2 and D3 may not be grounded after the bonding status associated with the conductive connectors 150 is monitored. That is, the first, second and third daisy chains D1, D2 and D3 may be floating.

In some cases, if a certain number of the conductive connectors 150 are found to have problems such as misalignment, poor bonding, or the like, the bonded structure 10 may be scrapped or re-worked. In some embodiments, the method 500 can be used as a reference for adjusting parameters of a bonding process of two semiconductor structures.

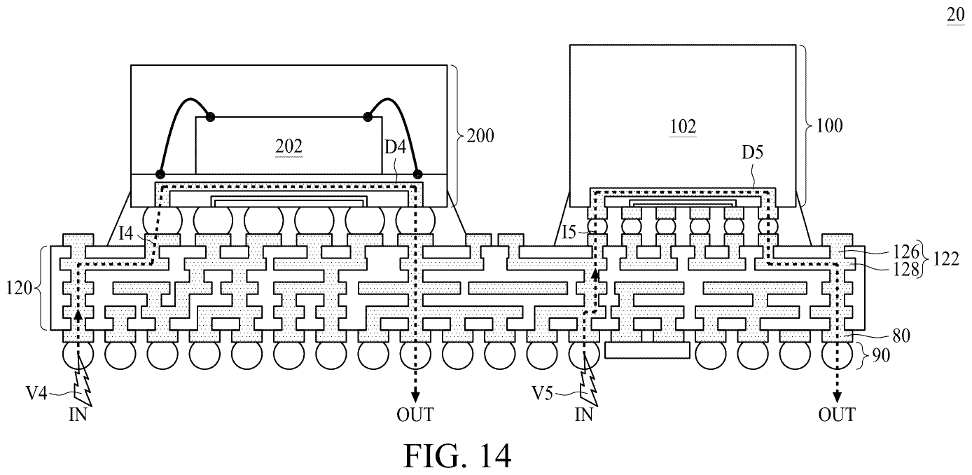

The method 500 can also be used for inspecting a bonding status of the bonded structure 20 in FIG. 4. FIGS. 14 to 16 are cross-sectional views showing some operations of the method 500 used for the bonded structure 20.

Referring to FIG. 14, in some embodiments, a fourth voltage V4 is applied to one of the conductive connectors 90 under an edge of the second semiconductor structure 200. In some embodiments, the fourth voltage V4 drives a fourth electrical current I4 to flow from the conductive connector 90 to another one of the conductive connectors 90 under another edge of the second semiconductor structure 200. The fourth electrical current I4 flows through the RDL 120, the conductive connectors below the second semiconductor structure 200, and a fourth daisy chain D4 associated with the second semiconductor structure 200. In some embodiments, the fourth voltage V4 is used to measure an electrical parameter or signal such as an electrical resistance of the fourth daisy chain D4. A fourth electrical resistance can be obtained by dividing the fourth voltage V4 by the fourth electrical current I4.

In some embodiments, a fifth voltage V5 is applied to one of the conductive connectors 90 under an edge of the first semiconductor structure 100. In some embodiments, the fifth voltage V5 drives a fifth electrical current I5 to flow from the conductive connector 90 to another one of the conductive connectors 90 under another edge of the first semiconductor structure 100. The fifth electrical current I5 flows through the RDL 120, the conductive connectors below the first semiconductor structure 100, and a fifth daisy chain D5 associated with the first semiconductor structure 100. In some embodiments, the fifth voltage V5 is used to measure an electrical parameter or signal such as an electrical resistance of the fifth daisy chain D5. A fifth electrical resistance can be obtained by dividing the fifth voltage V5 with the fifth electrical current I5.

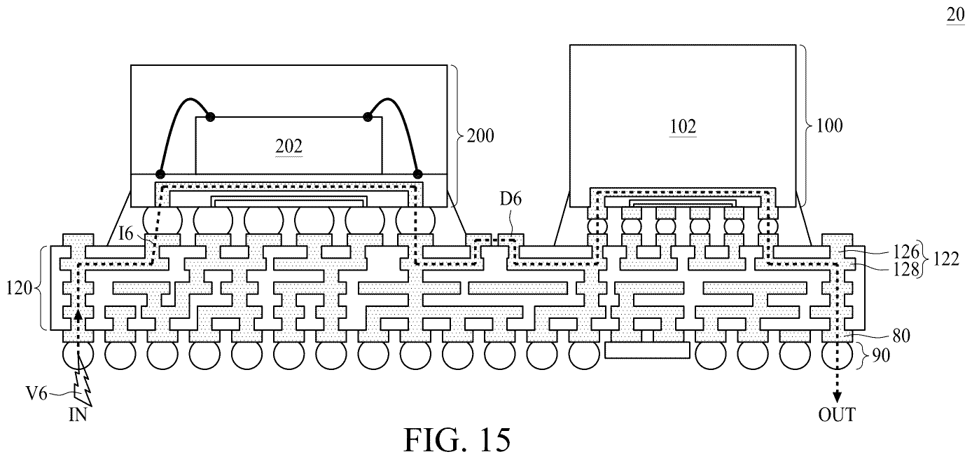

Referring to FIG. 15, in other embodiments, the redistribution wirings 122 in the RDL 120 electrically couple the first semiconductor structure 100 to the second semiconductor structure 200. In such embodiments, a sixth voltage V6 is applied to one of the conductive connectors 90 under an edge of the second semiconductor structure 200. In some embodiments, the sixth voltage V6 drives a sixth electrical current I6 to flow from the conductive connector 90 to another one of the conductive connectors 90 under an edge of the first semiconductor structure 100 farther from the edge of the second semiconductor structure 200. The sixth electrical current I6 flows through the RDL 120, the conductive connectors below the second semiconductor structure 200, the conductive connectors below the first semiconductor structure 100, and a sixth daisy chain D6 associated with the first and second semiconductor structures 100 and 200. In some embodiments, the sixth voltage V6 is used to measure an electrical parameter or signal such as an electrical resistance of the sixth daisy chain D6. A sixth electrical resistance can be obtained by dividing the sixth voltage V6 by the sixth electrical current I6.

In some embodiments, the fourth, fifth and sixth electrical resistances are used for evaluating a bonding status between the first semiconductor structure 100 and the RDL 120 and/or a joining status between the second semiconductor structure 200 and the RDL 120. The evaluations are similar to those described with reference to operation 505.

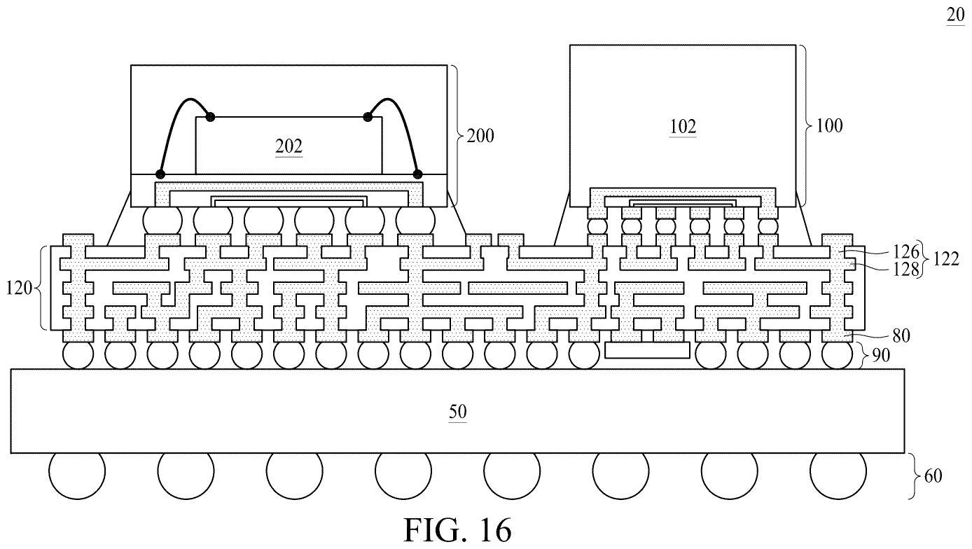

Referring to FIG. 16, the bonded structure 20 is mounted on the circuit board 50. In some embodiments, the conductive connectors 90 are grounded after an inspection of the bonding status of the bonded structure 20 is finished.

In the present disclosure, multiple daisy chains respectively form a network of various conductive connectors connecting two semiconductor structures. The daisy chains function as a test structure used for monitoring a yield of each conductive connector. According to electrical tests, reliability of the conductive connectors located at specific regions between the two semiconductor structures can be evaluated. In addition, the daisy chains do not influence functional circuits in the two semiconductor structures.

One aspect of the present disclosure provides a method for inspecting a bonded structure. The method includes: bonding a first semiconductor structure to a second semiconductor structure through a plurality of first conductive connectors between a first surface of the first semiconductor structure and the second semiconductor structure, wherein the first conductive connectors are electrically connected to each other by a plurality of first conductive lines within the second semiconductor structure; applying a voltage to the first conductive connectors through at least one of a plurality of second conductive connectors to obtain an electrical parameter, wherein the second conductive connectors are disposed at a second surface of the first semiconductor structure and electrically connected to the first conductive connectors; and evaluating a bonding status associated with the first conductive connectors according to the electrical parameter. The first conductive connectors are arranged adjacent to a corner or a periphery of the first semiconductor structure.

One aspect of the present disclosure provides another method for inspecting a bonded structure. The method includes: electrically testing a first chain disposed within and between a first semiconductor structure and a second semiconductor structure, wherein the first chain includes first conductive connectors joining the first semiconductor structure to the second semiconductor structure; obtaining a first electrical resistance associated with the first chain; evaluating a first joining status associated with the first conductive connectors according to the first electrical resistance; electrically testing a second chain disposed within and between the first semiconductor structure and the second semiconductor structure, wherein the second chain includes second conductive connectors joining the first semiconductor structure to the second semiconductor structure; obtaining a second electrical resistance associated with the second chain; and evaluating a second joining status associated with the second conductive connectors according to the second electrical resistance. The first chain is around the second chain.

Another aspect of the present disclosure provides a bonded structure. The bonded structure includes: a first semiconductor structure, including a first surface and a second surface opposite to the first surface; a second semiconductor structure, disposed over the first surface of the first semiconductor structure; a plurality of first conductive connectors, disposed between the second semiconductor structure and the first surface of the first semiconductor structure; a plurality of second conductive connectors disposed at the second surface of the first semiconductor structure; and a circuitry disposed between or within the first semiconductor structure and the second semiconductor structure, and electrically connecting the first conductive connectors to the second conductive connectors. The circuitry, the first conductive connectors and the second conductive connectors are electrically grounded.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for inspecting a bonded structure, comprising:
bonding a first semiconductor structure to a second semiconductor structure through a plurality of first conductive connectors between a first surface of the first semiconductor structure and the second semiconductor structure, wherein the first conductive connectors are electrically connected to each other by a plurality of first conductive lines within the second semiconductor structure;
applying a voltage to the first conductive connectors through at least one of a plurality of second conductive connectors to obtain an electrical parameter, wherein the second conductive connectors are disposed at a second surface of the first semiconductor structure and electrically connected to the first conductive connectors; and
evaluating a bonding status associated with the first conductive connectors according to the electrical parameter,
wherein the first conductive connectors are arranged adjacent to a corner or a periphery of the first semiconductor structure.

2. The method of claim 1, wherein the evaluation of the bonding status includes determining, based on the electrical parameter, whether a circuit is an open circuit or a closed circuit including the first conductive connectors.

3. The method of claim 1, wherein the electrical parameter is an electrical resistance or an electrical current associated with the first conductive connectors.

4. The method of claim 1, further comprising grounding the first conductive connectors after the application of the voltage.

5. The method of claim 4, wherein the grounding of the first conductive connectors includes providing a circuit board having a grounded trace, and bonding the first semiconductor structure to the circuit board to electrically connect the first conductive connectors to the grounded trace.

6. The method of claim 5, wherein the second conductive connectors electrically connected to the first conductive connectors are grounded after the bonding of the first semiconductor structure to the circuit board.

7. The method of claim 5, wherein the bonding of the first semiconductor structure to the circuit board is performed after the evaluation of the bonding status.

8. A method for testing a bonded structure, comprising:
electrically testing a first chain disposed within and between a first semiconductor structure and a second semiconductor structure, wherein the first chain includes first conductive connectors joining the first semiconductor structure to the second semiconductor structure;
obtaining a first electrical resistance associated with the first chain;
evaluating a first joining status associated with the first conductive connectors according to the first electrical resistance;
electrically testing a second chain disposed within and between the first semiconductor structure and the second semiconductor structure, wherein the second chain includes second conductive connectors joining the first semiconductor structure to the second semiconductor structure;
obtaining a second electrical resistance associated with the second chain; and
evaluating a second joining status associated with the second conductive connectors according to the second electrical resistance,
wherein the first chain is around the second chain.

9. The method of claim 8, wherein the first chain is closer to a periphery of the first semiconductor structure than the second chain.

10. The method of claim 9, wherein the electrical testing of the first chain and the electrical testing of the second chain are performed simultaneously.

11. The method of claim 8, wherein the electrical testing of the first chain includes applying a first voltage to the first chain, and the electrical testing of the second chain includes applying a second voltage to the second chain.

12. The method of claim 11, wherein the first voltage is identical to or different from the second voltage.

13. A bonded structure, comprising:
a first semiconductor structure, including a first surface and a second surface opposite to the first surface;
a second semiconductor structure, disposed over the first surface of the first semiconductor structure;
a plurality of first conductive connectors, disposed between the second semiconductor structure and the first surface of the first semiconductor structure;
a plurality of second conductive connectors disposed at the second surface of the first semiconductor structure; and
a circuitry disposed between or within the first semiconductor structure and the second semiconductor structure, and electrically connecting the first conductive connectors to the second conductive connectors,
wherein the circuitry, the first conductive connectors and the second conductive connectors are electrically grounded.

14. The bonded structure of claim 13, wherein the circuitry is electrically independent from functional circuitries within the first semiconductor structure and the second semiconductor structure.

15. The bonded structure of claim 13, wherein the first conductive connectors and the second conductive connectors are respectively ball grid array (BGA) bumps, micro-bumps or C4 bumps.

16. The bonded structure of claim 13, wherein the first conductive connectors are arranged adjacent to a corner or a periphery of the second semiconductor structure.

17. The bonded structure of claim 13, wherein the second conductive connectors are arranged adjacent to a corner or a periphery of the second surface of the first semiconductor structure.

18. The bonded structure of claim 16, wherein
a first region and a second region surrounded by the first region are defined adjacent to the periphery of the second semiconductor structure, and
a first group and a second group of the first conductive connectors are arranged within the first region and the second region, respectively.

19. The bonded structure of claim 13, wherein the first conductive connectors are electrically connected to each other in series.

20. The bonded structure of claim 13, further comprising a circuit board bonded to the first semiconductor structure by the second conductive connectors.
